(19) United States
(12) Patent Application Publication
(10) Pub. No.: US 2024/0377450 A1
(43) Pub. Date: Nov. 14, 2024

(54) YIELD EVALUATION METHOD AND YIELD EVALUATION APPARATUS

(71) Applicant: Winbond Electronics Corp., Taichung City (TW)

(72) Inventors: Tzi-Wen Pan, Hsinchu (TW); Chen-Kuang Su, Hsinchu City (TW)

(73) Assignee: Winbond Electronics Corp., Taichung City (TW)

(21) Appl. No.: 18/473,293

(22) Filed: Sep. 25, 2023

(30) Foreign Application Priority Data
May 11, 2023 (TW) 112117593

(51) Int. Cl. G01R 31/26

(52) U.S. Cl. CPC G01R 31/2601

(57) ABSTRACT

A yield evaluation method and a yield evaluation apparatus are provided. The method is described below. Wafer manufacturing data, front-end wafer test data, and back-end product yield information in a manufacturing process of a semiconductor product is collected and multiple parameters related to a yield are selected. A relative information entropy of a defective product in multiple samples manufactured using each of the parameters relative to a global constant probability defective product is calculated to establish a product entropy calculator. The global constant probability defective product represents the defective product whose yield does not vary with the parameters. The wafer manufacturing data and the front-end wafer test data of the current product are collected and substituted into the product entropy calculator to evaluate the yield of the current product.

### CROSS-REFERENCE TO RELATED APPLICATION

This application claims the priority benefit of Taiwan application serial no. 112117593, filed on May 11, 2023. The entirety of the above-mentioned patent application is hereby incorporated by reference herein and made a part of this specification.

### BACKGROUND

### Technical Field

The embodiment of this disclosure relates to an evaluation method and an apparatus, and more particularly, to a yield evaluation method and a yield evaluation apparatus.

### Description of Related Art

In the semiconductor industry, the cost of package testing accounts for a large portion of the overall production cost of chip manufacturers. Among the shipped products, there will be a huge difference in package testing cost due to the difference in the specification of the shipped product. For example, for memory chip products with the same density, the cost of car grade package testing will be nearly twice as much as that of commerce grade. Therefore, if the yield of a high-spec product is not high, the package testing will cause a considerable loss of profit. Thus, after the chip has completed the front-end manufacturing and testing, the person in charge of product engineering must carefully classify the finished products to the appropriate specification in order to properly control the cost of package testing. For example, sending chips with potentially lower yield to lower specification package testing, while products with potentially higher yield are subjected to high specification package testing, allows for greater shipment volume and cost control.

FIG. 1 shows a basic flow for determining the product packaging specification, which includes wafer product manufacturing 12, front-end wafer testing 14, back-end yield evaluation 16, and package testing 18. The package testing 18 may be divided into high-spec package testing 182 and low-spec package testing 184. The back-end yield evaluation 16 is based on the manufacturing data and testing data obtained from the wafer product manufacturing 12 and the front-end wafer testing 14, which determines whether the product undergoes the high-spec package testing 182 or the low-spec package testing 184. At this stage, an early approach involved the involvement of an expert 162 in the field, who made judgments on the product based on their expertise and knowledge. In recent years, many companies have implemented machine learning-assisted system 164, such as deep neural networks (DNN) and random forest, to assist in decision-making processes. These systems aim to increase efficiency and address potential shortcomings associated with human judgment. Although machine learning may handle a large amount of complex data, however, because of its complex mathematical model, there are often some unavoidable shortcomings.

For example, artificial neural networks can synthesize complex yield functions by utilizing non-linear functionals superposition, a concept derived from linear algebra. However, since achieving optimal fitting requires the use of deep and multi-layered network models, the results often yield complex combinations of data that are difficult to interpret. This significantly reduces the flexibility of practical application. For example, if users encounter information gaps or changes in testing when collecting future data, they will not be able to reconstruct the model and select appropriate data to input into it. In such situations, users often have to retrain the model.

### SUMMARY

The disclosure provides a yield evaluation method and an apparatus. By establishing an entropy calculator and using the same to evaluate a product yield and a packaging strategy, product shipments may be increased and production cost may be reduced.

An embodiment of the disclosure provides a yield evaluation method adapted for an electronic apparatus having a processor. The method is described below. Wafer manufacturing data, front-end wafer test data, and back-end product yield information in a manufacturing process of a semiconductor product is collected and multiple parameters related to a yield are selected. A relative information entropy of a defective product in multiple samples manufactured using each of the parameters relative to a global constant probability defective product is calculated to establish a product entropy calculator. The global constant probability defective product represents the defective product whose yield does not vary with the parameters. The wafer manufacturing data and the front-end wafer test data of a current product is collected and substituted into the product entropy calculator to evaluate the yield of the current product.

An embodiment of the disclosure provides a yield evaluation apparatus, which includes a connecting apparatus, a storage device, and a processor. The connecting apparatus is configured to connect multiple machines related to manufacturing and testing a semiconductor product. The storage device is configured to store a computer program. The processor is coupled to the connecting apparatus and the storage device and configured to load and execute the computer program for collecting wafer manufacturing data, front-end wafer test data, and back-end product yield information in a manufacturing process of a semiconductor product from the machines using the connecting apparatus and selecting a plurality of parameters related to a yield; and calculating a relative information entropy of a defective product in multiple samples manufactured using each of the parameters relative to a global constant probability defective product to establish a product entropy calculator. The global constant probability defective product represents the defective product whose yield does not vary with the parameters. The wafer manufacturing data and the front-end wafer test data of a current product is collected from the machines using the connecting apparatus and substituted into the product entropy calculator to evaluate the yield of the current product.

Based on the above, the yield evaluation method and the apparatus of the disclosure replace the original complex model with the product entropy calculator constructed, and random variables required for the original fitting are replaced with fixed variables. In this way, users can have a clearer understanding of the model and the results produced to determine packaging strategies based on this result.

### BRIEF DESCRIPTION OF THE DRAWINGS

FIG. 1 shows a basic flow for determining a product packaging specification.

FIG. 2 is a comparison diagram of yield evaluation methods according to an embodiment of the disclosure.

FIG. 3 is a block diagram of a yield evaluation apparatus according to an embodiment of the disclosure.

FIG. 4 is a flow chart of a yield evaluation method according to an embodiment of the disclosure.

FIG. 5 is a schematic view of establishing an entropy calculator based on an embodiment of the disclosure.

FIG. 6A to FIG. 6C are examples of calculating an information entropy according an embodiment of the disclosure.

FIG. 7 is a flow chart of establishing an entropy calculator according to an embodiment of the disclosure.

FIG. 8A and FIG. 8B are examples of calculating a weight according to an embodiment of the disclosure.

FIG. 9A and FIG. 9B are weight tables according to an embodiment of the disclosure.

### DESCRIPTION OF THE EMBODIMENTS

The embodiment of the disclosure addresses major shortcomings of conventional yield evaluation methods using machine learning. By utilizing the definition of information entropy and applying the extreme gradient boosting (XGBoost) model, a more interpretable result can be obtained. This result allows users to have greater flexibility in applications. The independence between each variable allows users to have more choices and variability when collecting future data. Furthermore, the inspection and debugging capabilities of the model may be improved to a certain extent.

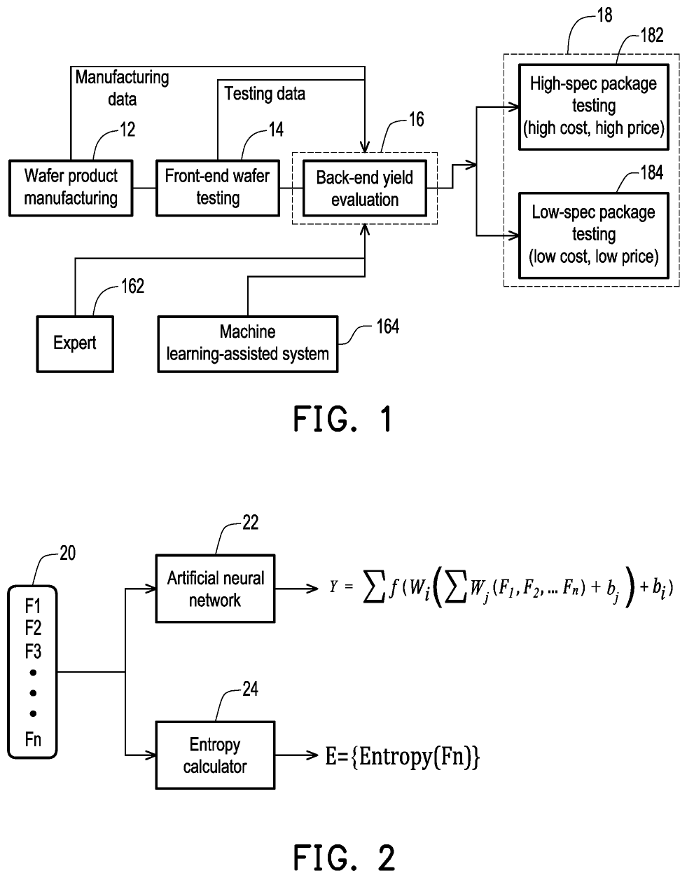

Referring to FIG. 2, current mainstream machine learning method in the industry is to use an artificial neural network 22, which mainly utilizes the method of linear algebra to input each parameter 20 (including parameters F1˜Fn) into an activator for non-linear transformation, and then optimizes the conditions through an optimizer. Finally, the functionals formed by the original parameters is superimposed into a complex yield function Y. In the process, it is necessary to set coefficients bi and bj and use a large number of random variables for weights Wi and Wj to achieve the best fitting result through the continuously optimized process.

Although the artificial neural network 22 may generate a large number of random variables and optimize the process to achieve the purpose of fitting complex yield functions, due to the introduction of too many and complicated variables, the user may not really explain and understand the final result.

In addressing this issue, the embodiment of the disclosure replaces the complex model methods, such as the artificial neural network 22, with an entropy calculator 24 based on information entropy derived from data science, eliminating the need for continuous optimization to achieve a fit for the yield function in the complex model. The random variables originally required for fitting is replaced by fixed variables. In this way, users can have a clearer understanding of the model and the results produced to determine packaging strategies based on this result.

In response to the entropy calculator 24 of this embodiment calculating the performance of the parameters and the sample yield, each of the parameters (such as Fn) independently calculates an information entropy E thereof relative to the performance of yield. Thus, there is a lot of flexibility in use. In response to the parameters of a new product being different from the parameters used in model construction, a simple filter may be used to process the input parameters without rebuilding the model.

In addition, through the entropy calculator 24, the amount of data to be collected during training may be greatly reduced. In response to using a small sample, it is still possible to construct a screening model through the information entropy change relationship between parameters.

Referring to FIG. 3, a yield evaluation apparatus 30 of this embodiment is, for example, an electronic apparatus such as a file server, a database server, an application server, a workstation, or a personal computer with computing ability. In some embodiments, the yield evaluation apparatus 30 is connected with the semiconductor manufacturing and test-related machines through a connecting apparatus 32. In other embodiments, the yield evaluation apparatus 30 may be integrated into the above machines for yield evaluation, which is not limited thereto. The yield evaluation apparatus 30 includes the connecting apparatus 32, a storage device 34, and a processor 36, and the functions of each element are described as follows.

The connecting apparatus 32 is, for example, any wired or wireless interface apparatus configured to connect with external apparatus such as the manufacturing machine and the testing machine of the semiconductor product and transmit data. For wired method, the connecting apparatus may be a universal serial bus (USB), RS232, a universal asynchronous receiver/transmitter (UART), an inter-integrated circuit (I2C), or a serial peripheral interface (SPI), but not limited thereto. For the wireless method, the connecting apparatus may be an apparatus supporting communication protocols such as wireless fidelity (Wi-Fi), RFID, bluetooth, infrared, near field communication (NFC), or device-to-device (D2D), and is not limited thereto. In some embodiments, the connecting apparatus 32 is, for example, a network card that supports wired network connections such as Ethernet or a wireless network card that supports wireless communication standards such as IEEE 802.11n/b/g, which may be connected to the network through wired or wireless methods to be connected to the above machines to extract data.

The storage device 34 is, for example, any type of fixed or removable random access memory (RAM), read-only memory (ROM), flash memory, hard disk, or other recording media, that is used to store the computer program executable by the processor 36 and the data extracted by the connecting apparatus 32. In some embodiments, the storage device 34 may store the related data (e.g., weight table) of the product entropy calculator established by the processor 36, but this embodiment is not limited thereto.

The processor 36 is, for example, a central processing unit, or other programmable general-purpose or special-purpose microprocessor, microcontroller, digital signal processor, programmable controller, application-specific integrated circuit, programmable logic device, or other similar devices or combinations of the foregoing, and the disclosure is not limited thereto. In this embodiment, the processor 36 may load the computer program from the storage device 34 to execute the yield evaluation method of the embodiment of the disclosure.

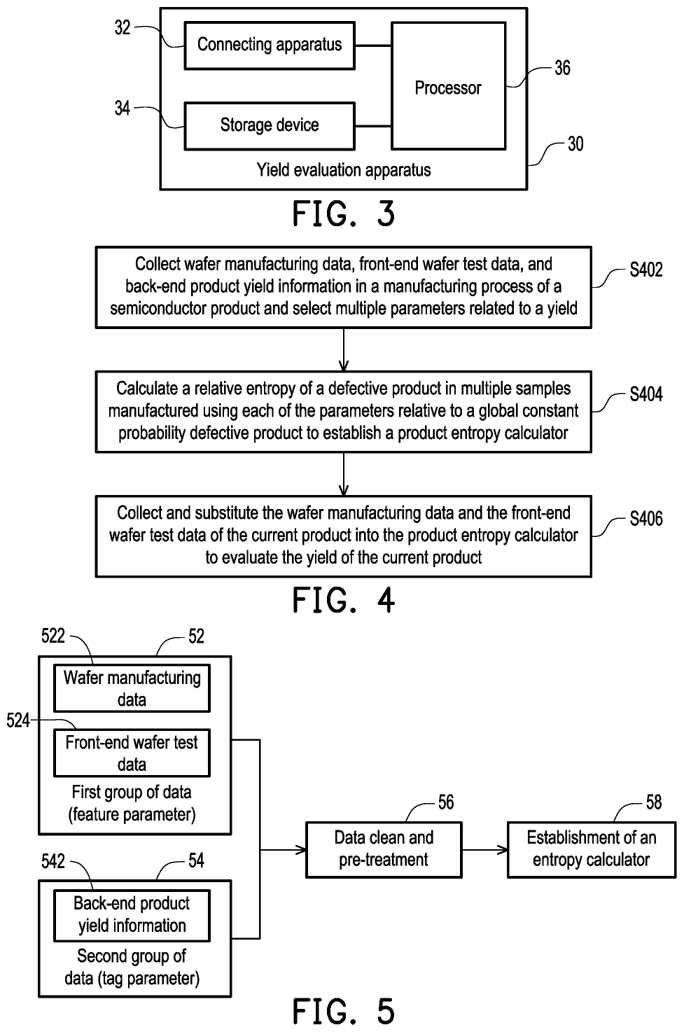

Referring to FIG. 3 and FIG. 4, the method of this embodiment is applicable to the yield evaluation apparatus 30 shown in FIG. 3.

In step S402, the processor 36 of the yield evaluation apparatus 30 uses the connecting apparatus 32 to connect the machines related to semiconductor manufacturing and testing to collect wafer manufacturing data, front-end wafer test data, and back-end product yield information in a manufacturing process of a semiconductor from the machines and select multiple parameters related to a yield.

The aforementioned wafer manufacturing data is, for example, wafer acceptance test (WAT) data, or inline process data such as critical dimension of the apparatus, as well as exposure shifting. The front-end wafer test data is, for example, chip probe results including yield and failure rate of each item, or direct current (DC) testing data. This embodiment does not limit the type and quantity of the above data.

In addition, the machines are, for example, semiconductor manufacturing machines or testing machines, or a machine that stores a database of wafer manufacturing data, front-end wafer test data, and back-end product yield information. This embodiment does not limit the type and quantity of the machines.

In detail, the yield evaluation method of the embodiment of the disclosure is mainly divided into two stages, which are the establishment of the entropy calculator and the production flow after the selection strategy method is imported. In the initial stage of establishing the entropy calculator, product information of a certain reference period is selected and collected, which includes the wafer manufacturing data, the front-end wafer test data and the back-end product yield information, and the entropy calculator of the product is constructed based on these data.

Referring to FIG. 5, this embodiment collects data first. The collected data are divided into two groups. A first group of data 52 is a model parameter (as a feature parameter) including wafer manufacturing data 522 and front-end wafer test data 524. A second group of data 54 is product yield information 542 (as a tag parameter) for a back-end testing. Then, performing the data cleaning and pre-treatment 56 on collected data first, which includes making some basic hypotheses based on the product information provided by experts in the field and projecting the collected data into a hypothetical math space based on these hypotheses, so as to facilitate the subsequent calculations established by the entropy calculator. After all the data is processed and projected into the hypothetical math space, the establishment of an entropy calculator 58 is started.

Returning to the flow in FIG. 4, in step S404, the processor 36 calculates a relative information entropy of a defective product in multiple samples manufactured using each of the parameters relative to a global constant probability defective product to establish a product entropy calculator. The global constant probability defective product represents the defective product whose yield does not vary with the parameters.

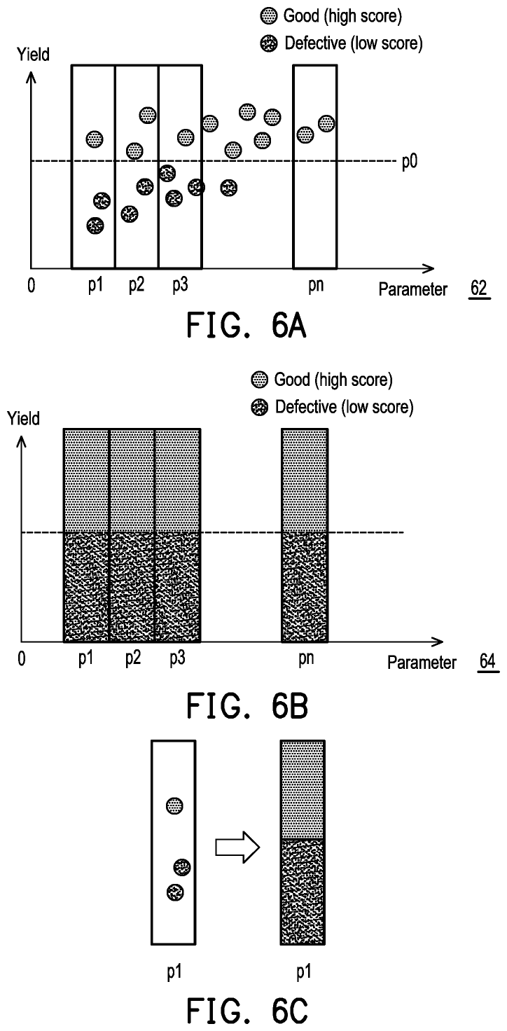

FIG. 6A to FIG. 6C are examples of calculating an information entropy according an embodiment of the disclosure. Referring to FIG. 6A, the process begins by selecting one parameter, and a relationship diagram 62 between the yield and the parameter is drawn. Next, the diagram is divided into n regions based on the size, each labeled with a number from p1 to pn. Finally, a partition standard p0 is selected as the standard for distinguishing between good and defective products. Products above this standard are considered as good products, while those below this standard are classified as defective products. In actual operation, m standard may be selected to calculate information entropy, respectively, where m is a positive integer.

Referring to FIG. 6B, this embodiment defines another situation where yield does not vary with a parameter and draws the relationship diagram 64 of the yield against the parameter.

After defining the “good or defective product”, this embodiment calculates the relative information entropy value of each “partition defective product” against the “global constant probability defective product”, as shown in FIG. 6C. The relative information entropy value of the defective product of the region p1 in the relationship diagram 62 against that of the global constant probability defective product of the region p1 in the relationship diagram 64 is calculated. In this way, the relative information entropy value on the yield performance of the parameter in each region may be obtained. This relative information entropy value may represent “the intensity of the uncertainty or surprise for yield performance of the parameters”. The formula for calculating the relative information entropy value Entropy is as follows.

Entropy=−(pn−p0)log(p0).

pn is the above-mentioned “partition defective product”, and p0 is the above-mentioned “global constant probability defective product”. The greater the value of this relative information entropy Entropy, the less the distribution of the sample resembles the “behavior of constant proportion”. In other words, the more it resembles a behavior of constant proportion, the more surprising it is.

In terms of cooperation, this embodiment may give the parameter a relative weight according to the hypothesis of the product information on the data to describe the relationship between the parameter and yield. Finally, according to the above process, the relationship between all parameters and yield performance is calculated in sequence and recorded in the storage device 34, which completes the establishment of the entropy calculator of the product.

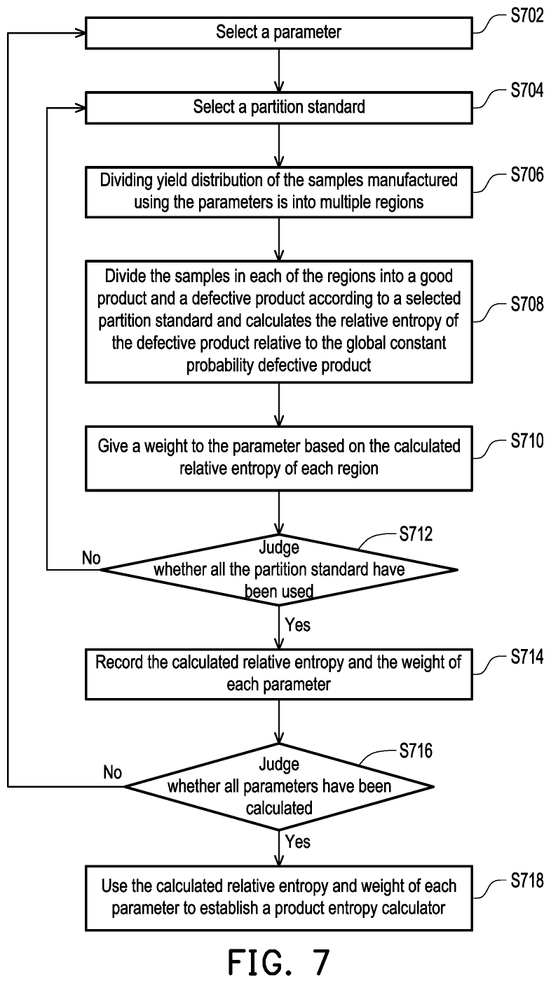

Referring to FIG. 7, this embodiment illustrates the detailed flow of step S404 in FIG. 4.

In step S702, the processor 36 selects one parameter from multiple parameters related to yield.

In step S704, the processor 36 selects one partition standard from multiple partition standards. In some embodiments, the processor 36, for example, sets a partition standard for every predetermined value or ratio for the yield range and selects the partition standard for calculating the relative information entropy. For example, the processor 36 may respectively select 20%, 40%, 60%, and 80% of the maximum value of yield as the partition standard.

In step S706, the yield distribution of the samples manufactured using the parameters is divided into multiple regions by the processor 36. The processor 36, for example, divides the range of the parameters of the yield distribution into multiple regions at intervals of a predetermined value or ratio (as shown in FIG. 6A).

In step S708, the processor 36 divides the samples in each of the regions into a good product and a defective product according to a selected partition standard and calculates the relative information entropy of the defective product relative to the global constant probability defective product, respectively.

In step S708, the processor 36 gives a weight to the selected parameter according to the calculated relative information entropy of each region. More specifically, for the weighting, this embodiment only gives a higher weight to “parameters with directional change behavior”. For example, if the greater the parameter value, the lower the information entropy value, then the parameter is judged to have a directional change behavior, and a weight is given; if the lower the parameter value, the lower the information entropy value, then the parameter is judged to have a directional change behavior, and a weight is given. It should be noted that if the information entropy value becomes negative, it is considered meaningless according to the definition thereof, and is thus set to zero and not taken into consideration.

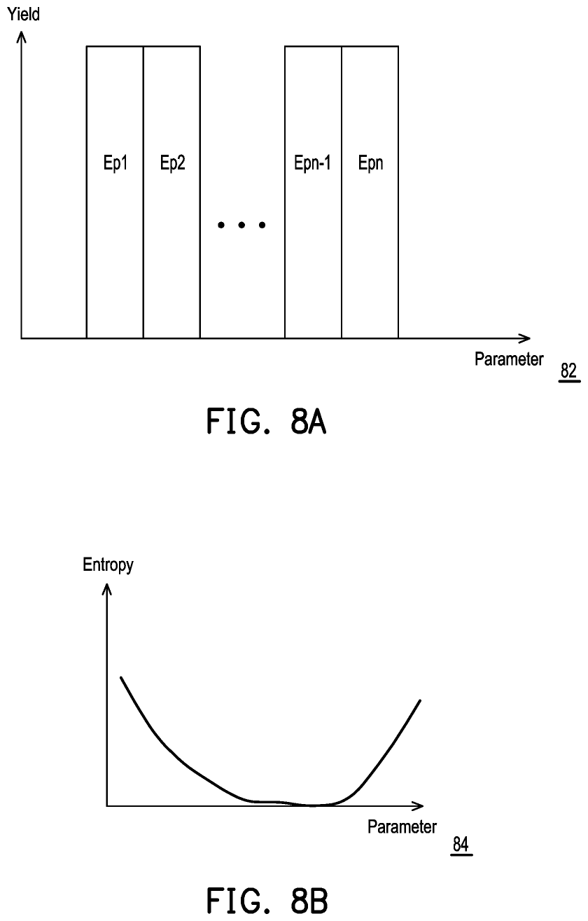

For example, FIG. 8A and FIG. 8B are examples of calculating the weight according to the embodiment of the disclosure. FIG. 8A shows a distribution chart 82 of the relative information entropy calculated through the example of FIG. 6A to FIG. 6C, which includes the relative information entropy Ep1˜Epn calculated for n regions. FIG. 8B shows the variation relationship diagram 84 of the relative information entropy, and this embodiment gives weight to the parameter according to the variation relationship diagram 84.

For the relative information entropy Ep1˜Epn in the distribution chart 82, this embodiment first sets the relative information entropy with a negative value to zero, and weight is not given to the parameter at this time.

In the case where the information entropy value decreases with increasing parameters, this embodiment compares the relative entropies Ep(n−1) and Ep(n) between adjacent regions. In response to the relative information entropy Ep(n) of a current region being greater than the relative information entropy Ep(n−1) of a previous region, the relative information entropy Ep(n) of the current region is set as the relative information entropy Ep(n−1) of the previous region, that is, Ep(n)=Ep(n−1), and the weight given to the parameters is increased. In response to the relative information entropy Ep(n) of the current region not being greater than the relative information entropy Ep(n−1) of the previous region, the relative information entropy Ep(n) of the current region is maintained.

On the other hand, in the case where the information entropy value increases with decreasing parameters, this embodiment further compares the relative entropies Ep(n−1) and Ep(n) between adjacent regions. In response to the relative information entropy Ep(n) of the current region being less than the relative information entropy Ep(n−1) of the previous region, the relative information entropy Ep(n) of the current region is set as the relative information entropy Ep(n−1) of the previous region, that is, Ep(n)=Ep(n−1), and the weight given to the parameters is increased. In response to the relative information entropy Ep(n) of the current region not being less than the relative information entropy Ep(n−1) of the previous region, the relative information entropy Ep(n) of the current region is maintained.

Through the above method, the relative information entropy calculated by using the selected partition standard for the selected parameter and the weight given to the parameter may be obtained.

Next, in step S712, the processor 36 judges whether all the partition standard have been used. If there are still unused partition standards, it is returned to step S704. The partition standard is selected again, and steps S706˜S710 are repeated to obtain the relative information entropy calculated using different partition standard and the weight given to the parameter.

In step S712, if it is determined that all the partition standard have been used, then enter step S714, and the processor 36 records the calculated relative information entropy and the weight of each parameter in the storage device 34. The processor 36 records the above relative information entropy and the weight, for example, in the form of a table.

In step S714, the processor 36 judges whether the relative information entropy and the weight have been calculated for all parameters. If there are still parameters that have not been calculated, it is returned to step S702. A parameter is selected again, and steps S704˜S714 are repeated to obtain the weights for different parameters.

In step S716, if it is determined that all parameters have been calculated, then enter step S718, and the processor 36 uses the calculated relative information entropy and weight of each parameter to establish a product entropy calculator. The processor 36, for example, superimposes the weights calculated using different partition standards for each parameter as the weight given to the parameter.

Returning to the flow in FIG. 4, after establishing the product entropy calculator, in step S406 the processor 36 collects and substitutes the wafer manufacturing data and the front-end wafer test data of the current product into the product entropy calculator to evaluate the yield of the current product. The processor 36, for example, calculates a sum of the weight corresponding to the parameters as a score for evaluating the yield of the current product for the parameters used to manufacture the current product. After that, the processor 36 may determine the packaging and testing specification adapted to the current product according to the score of the yield.

Specifically, in this stage, this embodiment collects the manufacturing data and the front-end testing data of a target batch of products and substitutes the same into the previously established product entropy calculator to calculate the corresponding weight scores of each product and produce a selection strategy of the packaging and testing specification of the product. According to the selection strategy, the packaging and testing cost management and control may be carried out.

For example, for a product with a high yield score (e.g., exceeding a predetermined threshold value), it may be sent to a high-spec package testing. For a product with a low yield score (e.g., below a predetermined threshold value), it may be sent to a low-spec package testing. In this way, the shipments of the product may be increased and the production cost may be reduced.

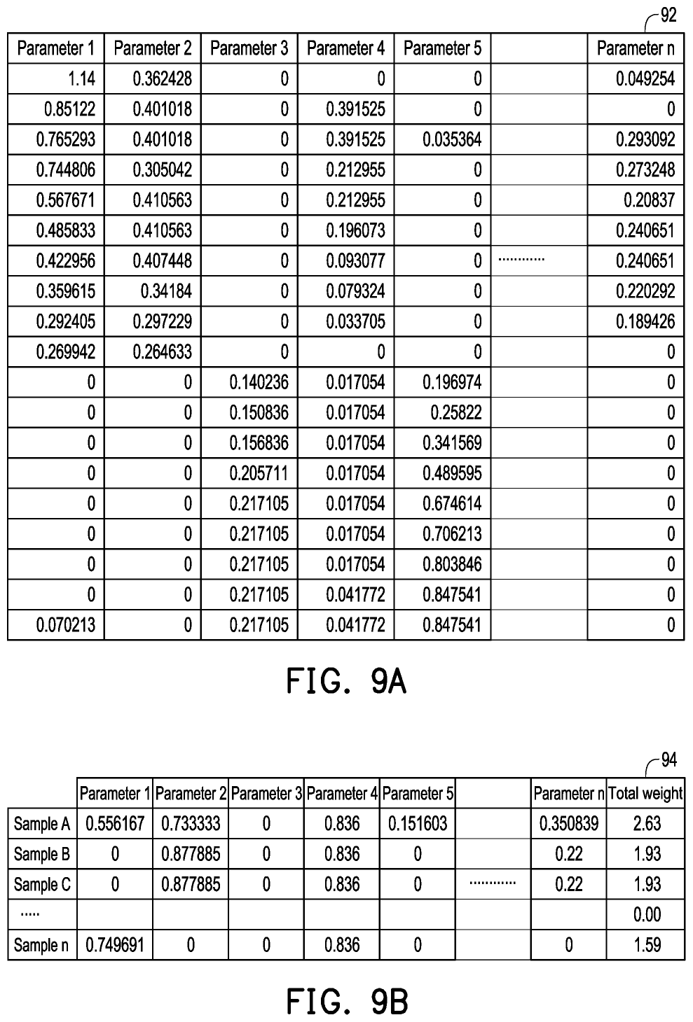

FIG. 9A and FIG. 9B are weight tables according to an embodiment of the disclosure. In a weight table 92 shown in FIG. 9A, the weights of each of the parameters (including parameters 1˜n) calculated through the flow of FIG. 7 are depicted. In the weight table 92, the weights from top to bottom represent the weights of each of the regions in the direction of increasing parameters. According to this weight table 92, the weight corresponding to each of the parameters of each of the samples may be found, and a sample weight table 94 shown in FIG. 9B may be obtained. The total weight may be obtained by summing up the weights of each of the parameters of each of the samples (including samples A˜n), and this total weight may be used as a reference value for evaluating the sample rank.

To sum up, in the yield evaluation method and the apparatus of the embodiment of the disclosure, the information entropy relative to each of the parameters relative to the yield is separately and independently calculated when calculating the performance of the parameters and the yield of the samples. Thus, much more flexibility is provided in terms of usage. In response to the parameters of a new product being different from the parameters used in model construction, a simple filter may be used to process the input parameters without rebuilding the model. By using the entropy calculator, the amount of data to be collected during training may be greatly reduced. Through screening of the entropy calculator, the variable parameters may be excluded and not included in the weight calculation, so as to obtain a set of suitable weight scores and selection strategies, and then achieve the purpose of controlling the cost of packaging and testing.

Although the disclosure has been described in detail with reference to the above embodiments, they are not intended to limit the disclosure. Those skilled in the art should understand that it is possible to make changes and modifications without departing from the spirit and scope of the disclosure. Therefore, the protection scope of the disclosure shall be defined by the following claims.

What is claimed is:

1. A yield evaluation method, adapted for an electronic apparatus having a processor, comprising:
collecting wafer manufacturing data, front-end wafer test data, and back-end product yield information in a manufacturing process of a semiconductor product and selecting a plurality of parameters related to a yield;
calculating a relative information entropy of a defective product in a plurality of samples manufactured using each of the parameters relative to a global constant probability defective product to establish a product entropy calculator, wherein the global constant probability defective product represents the defective product whose yield does not vary with the parameters; and
collecting and substituting the wafer manufacturing data and the front-end wafer test data of a current product into the product entropy calculator to evaluate the yield of the current product.

2. The method according to claim 1, wherein calculating the relative information entropy of the defective product in the samples manufactured using each of the parameters relative to the global constant probability defective product to establish the product entropy calculator comprises:
dividing a yield distribution of the samples manufactured using the parameters into a plurality of regions for each of the parameters;
dividing the samples in each of the regions into a good product and a defective product according to at least one partition standard and calculating the relative information entropy of the defective product relative to the global constant probability defective product, respectively;
giving the parameters a weight according to a calculated relative information entropy of each of the regions; and
establishing the product entropy calculator by using the calculated relative information entropy and the weight of each of the parameters.

3. The method according to claim 2, wherein giving the parameters the weight according to the calculated relative information entropy of each of the regions comprises:
setting the relative information entropy of a negative value to zero.

4. The method according to claim 3, wherein giving the parameters the weight according to the calculated relative information entropy of each of the regions further comprises:
comparing the relative information entropy of adjacent regions;
setting the relative information entropy of a current region as the relative information entropy of a previous region and increasing the weight given to the parameters in response to the relative information entropy of the current region in the regions being greater than the relative information entropy of the previous region; and
maintaining the relative information entropy of the current region in response to the relative information entropy of the current region in the regions not being greater than the relative information entropy of the previous region.

5. The method according to claim 3, wherein giving the parameters the weight according to the calculated relative information entropy of each of the regions further comprises:
comparing the relative information entropy of adjacent regions;
setting the relative information entropy of a current region as the relative information entropy of a previous region and increasing the weight given to the parameters in response to the relative information entropy of the current region in the regions being less than the relative information entropy of the previous region; and
maintaining the relative information entropy of the current region in response to the relative information entropy of the current region in the regions not being less than the relative information entropy of the previous region.

6. The method according to claim 2, wherein giving the parameters the weight according to the calculated relative information entropy of each of the regions comprises:
superimposing the weight calculated by using different partition standards as the weight given to the parameters.

7. The method according to claim 2, wherein dividing the yield distribution of the samples manufactured using the parameters into the regions for each of the parameters comprises:
dividing the yield distribution into the regions according to a predetermined value or ratio.

8. The method according to claim 2, wherein evaluating the yield of the current product comprises:
calculating a sum of the weight corresponding to the parameters as a score for evaluating the yield of the current product for the parameters used to manufacture the current product.

9. The method according to claim 1, wherein after collecting the wafer manufacturing data, the front-end wafer test data, and the back-end product yield information in the manufacturing process of the semiconductor product, further comprises:
performing data clean and pre-treatment on the wafer manufacturing data, the front-end wafer test data, and the back-end product yield information collected and projecting processed data into a hypothetical math space.

10. The method according to claim 1, wherein after evaluating the yield of the current product, the method further comprises:
determining a packaging and testing specification adapted to the current product based on the yield.

11. A yield evaluation apparatus, comprising:
a connecting apparatus, connecting a plurality of machines related to manufacturing and testing a semiconductor product;
a storage device, storing a computer program; and
a processor, coupled to the connecting apparatus and the storage device and configured to load and execute the computer program for:
collecting wafer manufacturing data, front-end wafer test data, and back-end product yield information in a manufacturing process of a semiconductor product from the machines using the connecting apparatus and selecting a plurality of parameters related to a yield;
calculating a relative information entropy of a defective product in a plurality of samples manufactured using each of the parameters relative to a global constant probability defective product to establish a product entropy calculator, wherein the global constant probability defective product represents the defective product whose yield does not vary with the parameters; and
using the connecting apparatus, collecting and substituting the wafer manufacturing data and the front-end wafer test data of a current product from the machines into the product entropy calculator to evaluate the yield of the current product.

12. The yield evaluation apparatus according to claim 11, wherein the processor comprises:
dividing a yield distribution of the samples manufactured using the parameters into a plurality of regions for each of the parameters;
dividing the samples in each of the regions into a good product and a defective product according to at least one partition standard and calculating the relative information entropy of the defective product relative to the global constant probability defective product, respectively;
giving the parameters a weight according to a calculated relative information entropy of each of the regions; and
establishing the product entropy calculator by using the calculated relative information entropy and the weight of each of the parameters.

13. The yield evaluation apparatus according to claim 12, wherein the processor comprises setting the relative information entropy of a negative value to zero.

14. The yield evaluation apparatus according to claim 13, wherein the processor further compares the relative information entropy of adjacent regions, wherein in response to the relative information entropy of a current region in the regions being greater than the relative information entropy of a previous region, the relative information entropy of the current region is set as the relative information entropy of the previous region and the weight given to the parameters is increased; and in response to the relative information entropy of the current region in the regions not being greater than the relative information entropy of the previous region, the relative information entropy of the current region is maintained.

15. The yield evaluation apparatus according to claim 13, wherein the processor further compares the relative information entropy of adjacent regions, wherein in response to the relative information entropy of a current region in the regions being less than the relative information entropy of a previous region, the relative information entropy of the current region is set as the relative information entropy of the previous region and the weight given to the parameters is increased; and in response to the relative information entropy of the current region in the regions not being less than the relative information entropy of the previous region, the relative information entropy of the current region is maintained.

16. The yield evaluation apparatus according to claim 12, wherein the processor comprises superimposing the weight calculated by using different partition standards as the weight given to the parameters.

17. The yield evaluation apparatus according to claim 12, wherein the processor comprises dividing the yield distribution into the regions according to a predetermined value or ratio.

18. The yield evaluation apparatus according to claim 12, wherein the processor comprises calculating a sum of the weight corresponding to the parameters as a score for evaluating the yield of the current product for the parameters used to manufacture the current product.

19. The yield evaluation apparatus according to claim 11, wherein the processor performs data clean and pre-treatment on the wafer manufacturing data, the front-end wafer test data, and the back-end product yield information collected and projects processed data into a hypothetical math space.

20. The yield evaluation apparatus according to claim 11, wherein the processor further determines a packaging and testing specification adapted to the current product based on the yield.
